(19) United States
(12) Patent Application Publication
(10) Pub. No.: US 2017/0215296 A1
(43) Pub. Date: Jul. 27, 2017

(54) MULTI-BAY APPARATUS

(71) Applicant: HEWLETT PACKARD ENTERPRISE DEVELOPMENT LP, Houston, TX (US)

(72) Inventors: Pinche TSAI, Richardson, TX (US); Kevin D CONN, Montgomery, TX (US); Mujeeb Ur REHMAN, Houston, TX (US); Chanh V HUA, Houston, TX (US)

(21) Appl. No.: 15/328,572

(22) PCT Filed: Jul. 30, 2014
(86) PCT No.: PCT/US2014/048866

§ 371 Date: Jan. 24, 2017

(51) Int. Cl. H05K 7/14; G06F 13/40; H01R 12/71; G06F 13/42

(52) U.S. Cl. CPC H05K 7/1487; G06F 13/4282; G06F 13/409; G06F 13/4068; H05K 7/1488; H01R 12/716; G06F 2213/0024; G06F 2213/0026

(57) ABSTRACT

A multi-bay apparatus can include a connector located in a multi-bay of a printed circuit assembly (PCA) of the apparatus, the connector is shaped to support a plurality of electronic input components at separate periods of time. The connector can connect an electronic input component among the plurality of electronic input components supported by the connector.

### BACKGROUND

Connectors can be used to connect electronic input components (e.g., server components, printed circuit boards, memory modules, etc.) within apparatuses, such as server cartridges in a computing system or network to one another. Multiple portions (e.g., terminals) of the connector may be connected to an electronic input component. The connector can transmit information (e.g., a signal) between the electronic input component and an apparatus.

### BRIEF DESCRIPTION OF THE DRAWINGS

FIG. 1 illustrates a diagram of an example of an apparatus according to the present disclosure.

FIG. 2 illustrates a diagram of an example of an apparatus and an electronic input component according to the present disclosure.

FIG. 3 illustrates a diagram of an example of an apparatus according to the present disclosure.

FIG. 4 illustrates a diagram of an example of a system according to the present disclosure.

### DETAILED DESCRIPTION

Flexibility of placement of electronic input components has become important for next generation server cartridges and/or other servers. For instance, a customer may request a server cartridge and/or other server that supports certain features currently not supported by the server cartridge and/or other servers. The features requested may result in a new server cartridge and/or server design such that the new server cartridge and/or server can support an electronic input component that provides the features requested by the customer. An electronic input component, as used herein, is any electronic component that can be input to an apparatus to provide a feature.

Due to the speed of computer technology, designing a new server cartridge and/or other server in response to a customer request can result in inefficient production time. The requesting customer may be lost due to delay in receiving the product that supports the requested feature.

In contrast, examples of the present disclosure include apparatuses with a universal connector in a multi-bay that can support a plurality of electronic input components. This can reduce the amount of time between a customer requesting a different feature and the customer receiving a product that supports the different feature (e.g., reducing production time). For instance, upon request of a new feature, an electronic input component can be connected to the universal connector to provide the newly requested feature.

A universal connector located in the multi-bay of an apparatus in accordance with the present disclosure can reduce the time between a customer requesting a feature and the customer receiving a product that supports the feature. Reduction of production time can result in greater efficiency and higher customer satisfaction.

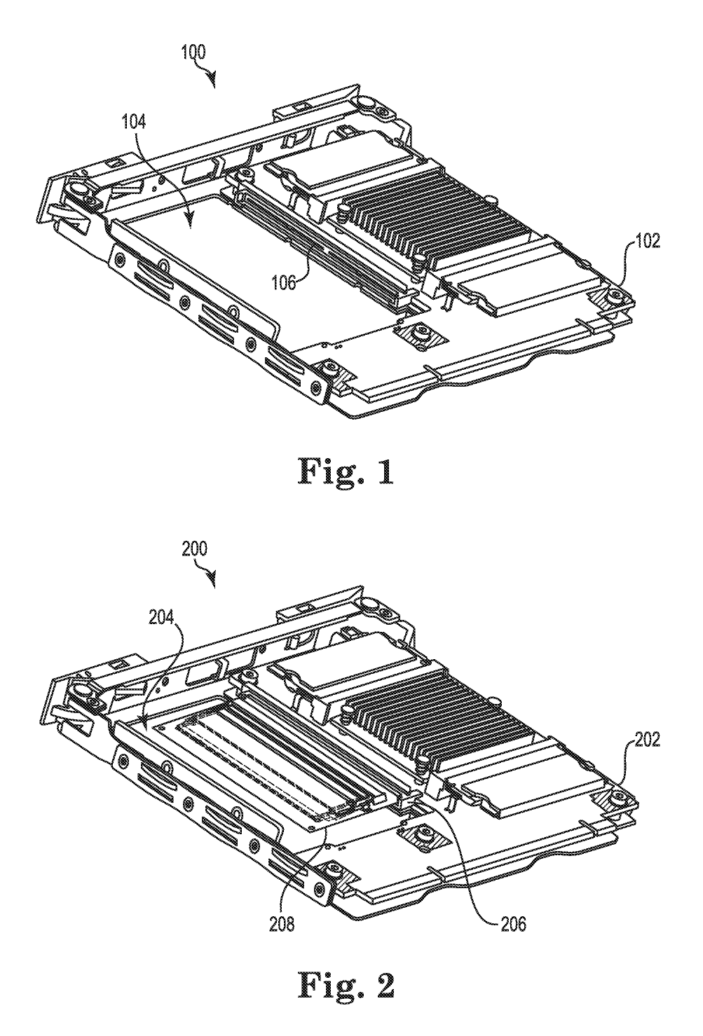

FIG. 1 illustrates a diagram of an example of an apparatus 100 according to the present disclosure. The apparatus 100 can include a server cartridge and/or other type of server. Example servers can include a blade server, a tower server, a rack server, a storage server, a maximized line (ML) server, and/or a density line (DL) server, among other types of servers.

A server cartridge, as used herein, can include a frame (e.g., a case) substantially surrounding a processor, a memory, and a non-volatile storage device coupled to the processor. A tower server can include a computer that is used as a server and built in an upright cabinet that stands alone. A rack server can include a computer that is used as a server and designed to be installed in a rack (e.g., a metal framework). A blade server can include a server chassis housing multiple thin, modular electronic circuit boards (e.g., server blades) and each blade is a server. An ML server can include tower servers in a rack. A DL server can include a server that does not share components (like power and cooling) with other servers (like a blade server). A storage server can include a type of server used to store, access, secure, and/or manage digital data, files, and/or services.

Apparatus 100 can include a printed circuit assembly (PCA) 102 with a multi-bay 104 located in the PCA 102. A PCA, as used herein, is a printed circuit board populated with electronic components (e.g., a processor, a memory, etc.). A multi-bay, as used herein, is an area of the apparatus 100 where a plurality of electronic input components can be installed, each at separate periods of time.

An electronic component, as used herein, is a discrete device and/or physical entity used to provide a feature. Further, as previously discussed, an electronic input component, as used herein, is an electronic component that can be input to an apparatus to provide a feature.

The multi-bay 104 and the PCA 102 can include a multi-bay PCA standard that can support a wide array of features. Each feature can be provided by, for instance, an electronic input component. For example, a connector 106 located in the multi-bay 104 of the PCA 102 of the apparatus 100 can be adapted to (e.g., structurally shaped to) support a plurality of electronic input components at separate periods of time.

A connector, as used herein, is a component that plugs into a port or interface to connect one apparatus to another (e.g., connects the apparatus 100 to an electronic input component). The connector 106 can include a universal connector. For example, the connector can include a straddle mount multi-bay connector, such as a Mobile Peripheral Component Interconnect (PCI) Express Module (MxM) connector. An MxM connector, as used herein, is a connector supporting MxM, among other standards. The connector 106 can connect an electronic input component among the plurality of electronic input components supported by the connector 106 to provide a feature (e.g., additional memory, graphics capabilities, storage, etc.).

For example, an MxM connector can be used to connect a variety of electronic input components and is not limited to connecting an MxM module. MxM, as used herein, is a interconnect standard for graphic processing units (CPUs) using PCI express. An MxM module can offload computing operations from the core processor to the graphics card, which is known as General-Purpose Computing on CPUs (GPGPU). For example, an MxM connector can accommodate electronic input component thicknesses of 12 millimeter (mm)±0.1.

As illustrated by FIG. 1, the connector 106 can include a rectangular shaped connector. The multi-bay 104 can include a rectangular shape and the connector 106 can be located on side of the multi-bay 104. Although examples in accordance with the present disclosure are not so limited and the connector and/or multi-bay can include a variety of shapes.

For instance, the connector 106 can connect electronic input components including memory modules and circuit boards, as well as other active, passive, an/or electromechanical electronic input components. In a number of examples, electronic input components can include server components, which can include electronic components located on or associated with a server or server blade, for instance. Example electronic input components can include an array of memory components, processing components, storage components, and graphic components.

FIG. 2 illustrates a diagram of an example of an apparatus 200 and an electronic input component 208 according to the present disclosure. Similarly to FIG. 1, the apparatus 200 includes a connector 206 located in a multi-bay 204 of a PCA 202 of the apparatus 200. The apparatus 200 illustrated by FIG. 2 can include the same apparatus 100 illustrated by FIG. 1, in various examples.

In a number of examples, the connector 206 can connect an electronic input component 208 among the plurality of electronic input components supported by the connector 206. For instance, the electronic input component 208 can include at least one of a dual in-line memory module (DIMM), a Mobile Peripheral Component Interconnect (PCI) Express Module (MxM) graphic card, an M.2 storage device, a solid-state drive (SSD) device, a system on chip processor device, and/or a small outline dual in-line memory module (SO-DIMM), among other electronic input components.

An apparatus 200 with a connector 206 (e.g., a universal connector) that is adapted to support a plurality of electronic input components at separate periods of time can decrease production time for providing particular features to a customer. The electronic input components can provide a wide array of features, such as graphics, storage, compute, and memory using the same multi-bay PCA standard. Upon receiving a request for a new feature, an electronic input component that can provide the new feature can be connected to the connector 206 and provided to the customer as a product. This can decrease the amount of time between a customer requesting a different feature and the customer receiving a product that supports the different feature (e.g., reducing production time).

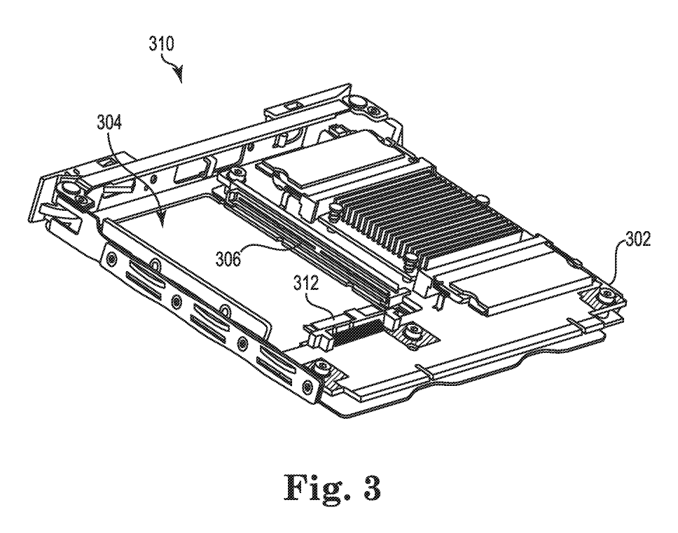

FIG. 3 illustrates a diagram of an example of an apparatus 310 according to the present disclosure. Similarly to FIGS. 1 and 2, the apparatus 310 includes a first connector 306 located in a multi-bay 304 of a PCA 302 of the apparatus 310.

In some examples, a plurality of connectors can be located in the multi-bay 304. For instance, a second connector 312 can be located in the multi-bay 304 of the PCA of the apparatus 310.

The first connector 306, in some examples, can include an MxM connector and the second connector 312 can include a Serial Advanced Technology Attachment (SATA) connector. SATA can include a computer bus interface that connects host bus adapters to mass storage devices such as hard disk drives and optical drives. A SATA connector can support point-to-point link with hot plugging capabilities and/or high speeds, among other features.

Although the present example of FIG. 3 illustrates two connectors, examples in accordance with the present disclosure are not so limited. For example, a multi-bay 304 in accordance with the present disclosure can include more than two connectors.

The first connector 306 can be adapted to support a first plurality of electronic input components, and the second connector 312 can be adapted to support a second plurality of electronic input components at separate periods of time. The first plurality of electronic input components and the second plurality of electronic input components can include different sets of electronic input components. That is, the first connector 306 and the second connector 312 can each support particular electronic input components.

For example, the first connector 306 can connect an electronic input component among the first plurality of electronic input components in the multi-bay 304. Alternatively and/or in addition, the second connector 312 can connect an electronic input component among the second plurality of electronic input components in the multi-bay 304.

In some examples, different electronic input components can be connected in the multi-bay 304 of the apparatus 310 (and/or the apparatus 100 illustrated in FIG. 1 and the apparatus 200 illustrated in FIG. 2) at separate periods of time. For instance, the first connector 306 can connect a first electronic input component in the multi-bay 304 and/or a second electronic input component in the multi-bay 304. The second connector 312 can connect a third electronic input component in the multi-bay 304.

The first electronic input component, the second electronic input component, and/or the third electronic input component can be connected at separate periods of time. For example, when using the apparatus 310 (and/or apparatus 100 illustrated in FIG. 1 and apparatus 200 illustrated in FIG. 2), different electronic input components can be connected at separate periods of time to provide different features.

As illustrated by FIG. 1, FIG. 2, and FIG. 3, the apparatuses 100, 200, 310 can include configurations to support the multi-bay 104, 204, 304 and the connector(s) 106, 206, 306, 312. The configuration can include a frame. A frame, as used herein, is a physical structure to support the multi-bay and the connector, for instance. The frame can provide the area for the multi-bay 104, 204, 304.

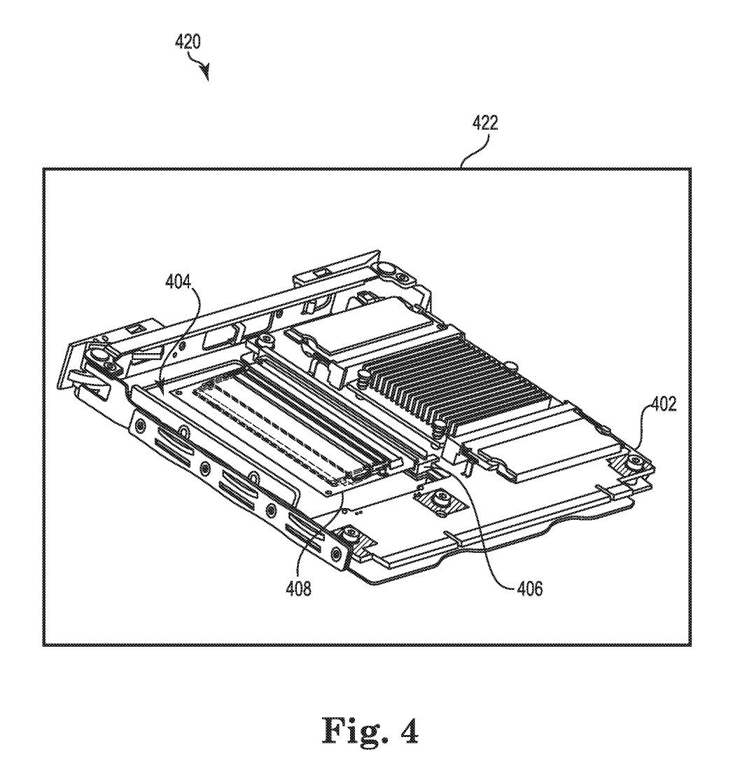

FIG. 4 illustrates a diagram of an example of a system 420 according to the present disclosure. System 420 includes an apparatus 422 with a PCA 402 and an electronic input component 408.

The apparatus 422 can include a server cartridge and/or other server (e.g., rack, tower, etc.) The apparatus 422 can include a multi-bay 404 located in the PCA 402, a universal connector 406 located in the multi-bay 404, and a frame to support the PCA 402 and the multi-bay 404.

The universal connector 406 can be adapted to support a plurality of electronic input components at separate periods of time. Each of the plurality of electronic input components can provide a particular feature.

As illustrated by FIG. 4, the system 420 can include an electronic input component 408 among the plurality of electronic input components supported by the universal connector 406. The electronic input component 408 can be connected to the universal connector 406.

In various examples, as illustrated by FIG. 3, the apparatus 422 can include a multi-bay 404 located in the PCA 402 that includes a plurality of connectors. Each connector of the plurality of connectors can be adapted to connect particular electronic input components.

Further, as previously discussed, a plurality of electronic input components can be connected to the universal connector 406. Each of the plurality of electronic input components can be connected at separate periods of time to provide different features.

By placing a universal connector 406 in a multi-bay 404 of an apparatus 422, new features can be quickly provided to customers as compared to some approaches. Upon receiving a request for a new feature, an electronic input component that can provide the new feature can be connected to the universal connector 406 and provided to the customer as a product. This can result in decreased production time and increased customer satisfaction and/or retention.

In the foregoing detailed description of the present disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical. and/or structural changes may be made without departing from the scope of the present disclosure.

The figures herein follow a numbering convention in which the first digit corresponds to the drawing figure number and the remaining digits identify an element or component in the drawing. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense. Further, as used herein, “a number of” an element and/or feature can refer to one or more of such elements and/or features.

As used herein, “logic” is an alternative or additional processing resource to perform a particular action and/or function, etc., described herein, which includes hardware, e.g., various forms of transistor logic, application specific integrated circuits (ASICs), etc., as opposed to computer executable instructions, e.g., software firmware, etc., stored in memory and executable by a processor.

What is claimed:

1. An apparatus, comprising:
a connector located in a multi-bay of a printed circuit assembly (PCA) of the apparatus, the connector adapted to:
support a plurality of electronic input components at separate periods of time; and
connect an electronic input component among the plurality of electronic input components supported by the connector.

2. The apparatus of claim 1, wherein the connector includes a universal connector.

3. The apparatus of claim 1, wherein the connector includes a straddle-mount multi-bay connector.

4. The apparatus of claim 1, wherein the connector includes a Mobile Peripheral Component Interconnect (PCI) Express Module (MxM) connector.

5. The apparatus of claim 1, wherein the electronic input component includes at least one of:
a dual in-line memory module (DIMM), a Mobile Peripheral Component Interconnect (PCI) Express Module (MxM) graphic card, an M.2 storage device, a solid-state drive (SSD) device, a system on chip processor device, and a small outline dual in-line memory module (SO-DIMM).

6. The apparatus of claim 1, wherein the apparatus includes a server cartridge.

7. The apparatus of claim 1, wherein the apparatus includes a server.

8. The apparatus of claim 7, wherein the server includes at least one of a blade server, a maximized line (ML) server, a density line (DL) server, a tower, a rack, and a storage server.

9. An apparatus, comprising:
a first connector located in a multi-bay of a printed circuit assembly (PCA) of the apparatus, the first connector adapted to:
support a first plurality of electronic input components at separate periods of time; and
connect an electronic input component among the first plurality of electronic input components in the multi-bay; and
a second connector located in the multi-bay of the PCA of the apparatus, the second connector adapted to support a second plurality of electronic input components at separate periods of time.

10. The apparatus of claim 9, wherein the multi-bay of the PCA supports an array of electronic input components, including the first plurality and the second plurality of electronic input components.

11. The apparatus of claim 9, wherein the multi-bay and the PCA include a multi-bay PCA standard.

12. The apparatus of claim 9, wherein the first connector includes a Mobile Peripheral Component Interconnect (PCI) Express Module (MxM) connector and the second connector includes a Serial Advanced Technology Attachment (SATA) connector.

13. The apparatus of claim 9, wherein:
the electronic input component is a first electronic input component; and
the second connector connects a second electronic component among the second plurality of electronic input components in the multi-bay, and
wherein the first electronic input component and the second electronic input component are connected at separate periods of time.

14. A system, comprising:
an apparatus including:
a printed circuit assembly (PCA);
a multi-bay located in the PCA;
a universal connector located in the multi-bay, wherein the universal connector is adapted to support a plurality of electronic input components at separate periods of time; and
a frame to support the PCA and the multi-bay; and
an electronic input component among the plurality of electronic input components supported by the universal connector, wherein the electronic input component is connected to the universal connector.

15. The system of claim 14, wherein the plurality of electronic input components include an array of memory components, processing components, storage components, and graphic components.
